(19) United States
(12) Patent Application Publication
(10) Pub. No.: US 2017/0163252 A1
(43) Pub. Date: Jun. 8, 2017

(54) SYSTEMS AND METHODS FOR IMPLEMENTING HYSTERESIS IN A COMPARATOR

(71) Applicant: Cirrus Logic International Semiconductor Ltd., Edinburgh (GB)

(72) Inventors: Vaibhav Pandey, Austin, TX (US); John L. Melanson, Austin, TX (US); Anindya Bhattacharya, Austin, TX (US)

(73) Assignee: Cirrus Logic International Semiconductor Ltd., Edinburgh (GB)

(21) Appl. No.: 14/962,615

(22) Filed: Dec. 8, 2015

(51) Int. Cl. H03K 5/24; H03K 3/3565

(52) U.S. Cl. CPC H03K 5/2481; H03K 3/3565

(57) ABSTRACT

In accordance with embodiments of the present disclosure, a comparator may include a transconductance stage having an input configured to receive an input voltage and generate an intermediate current responsive to the input voltage, a hysteretic current source configured to generate a hysteretic current, an output stage configured to generate an output signal based at least on the intermediate current, and a switch responsive to the output stage and configured to combine the intermediate current and the hysteretic current to generate a combined current, such that the output stage generates the output signal based at least on the intermediate current and the hysteretic current when output signal has a first value.

### FIELD OF DISCLOSURE

The present disclosure generally relates to switching circuits, and, more particularly, to systems and methods for implementing hysteresis in a comparator circuit.

### BACKGROUND

Many electronic devices on the market today often use comparator circuits. In general, a comparator circuit is a device that compares two voltages or currents and outputs a digital signal indicating which is larger. For example, an ideal voltage comparator may have a differential analog input voltage v with analog input terminals v⁺ and v⁻, and one binary digital output vₒᵤₜ, wherein v_{OUT}=1 when v⁺>v⁻, and v_{OUT}=0 otherwise. In practical applications, it may be desirable however, to deviate from an ideal response for a comparator to add hysteresis in order to prevent unwanted switching of the output vₒᵤₜ, for example, in situations in which the analog input signal vᵢₙ is noisy near the comparator's threshold switching point. For example, with added hysteresis, a response of a comparator may be such that output vₒᵤₜ switches from 0 to 1 if v⁺>V⁻+Δv, and/or output vₒᵤₜ switches from 1 to 0 if v⁻>v⁺+Δv₋, where Δv₊ and Δv₋ are non-zero values.

### SUMMARY

In accordance with the teachings of the present disclosure, certain disadvantages and problems associated with implementing programmable hysteresis in a comparator circuit may be reduced or eliminated.

In accordance with embodiments of the present disclosure, a comparator may include a transconductance stage having an input configured to receive an input voltage and generate an intermediate current responsive to the input voltage, a hysteretic current source configured to generate a hysteretic current, an output stage configured to generate an output signal based at least on the intermediate current, and a switch responsive to the output stage and configured to combine the intermediate current and the hysteretic current to generate a combined current, such that the output stage generates the output signal based at least on the intermediate current and the hysteretic current when output signal has a first value.

In accordance with these and other embodiments of the present disclosure, a method may include receiving an input voltage, generating an intermediate current responsive to the input voltage by a transconductance stage, generating a hysteretic current with a hysteretic current source, generating an output signal based at least on the intermediate current by an output stage, and controlling a switch responsive to the output stage such that the intermediate current and the hysteretic current are combined to generate a combined current, such that the output signal is based at least on the intermediate current and the hysteretic current when the output signal has a first value.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of a comparator with programmable hysteresis, in accordance with embodiments of the present disclosure;

FIG. 2 illustrates detailed circuit diagram of components of the example comparator of FIG. 1, in accordance with embodiments of the present disclosure; and

FIG. 3 illustrates an alternative detailed circuit diagram of components of the example comparator of FIG. 1, in accordance with embodiments of the present disclosure.

### DETAILED DESCRIPTION

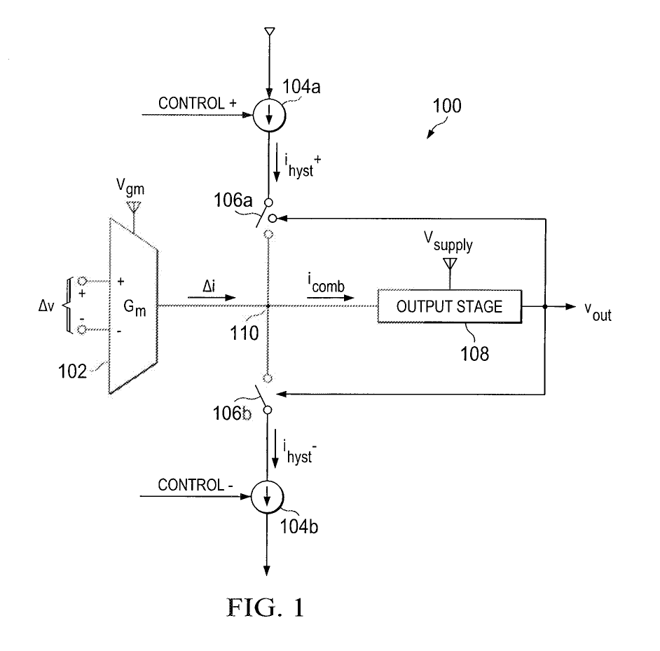

FIG. 1 illustrates a block diagram of a comparator 100 with programmable hysteresis, in accordance with embodiments of the present disclosure. As shown in FIG. 1, comparator 100 may include a transconductance stage 102, one or more hysteretic current sources 104 (e.g., hysteretic current sources 104a and 104b), one or more switches 106 (e.g., switches 106a and 106b), and an output stage 108.

Transconductance stage 102 may comprise any system, device, or apparatus (e.g., a transconductance amplifier) having an input configured to receive an input voltage signal Δv and generate an intermediate current signal Ai responsive to and a function of input voltage Δv. For example, transconductance stage 102 may apply a transconductance gain Gₘ such that Δi=GₘΔv. As shown in FIG. 1, transconductance stage 102 may include a transconductance stage power supply input for receiving a transconductance stage power supply voltage V_{gm} for powering transconductance stage 102 and its various components.

A hysteretic current source 104 may comprise any system, device, or apparatus configured to generate a hysteretic current. For example, as shown in FIG. 1, hysteretic current source 104a may generate a current i_{hyst}⁺ while hysteretic current source 104b may generate a current i_{hyst}⁻. As depicted, each hysteretic current source 104 may include a control input configured to receive a respective control signal (e.g., control signals CONTROL⁺ and CONTROL⁻) and may be configured to generate its respective hysteretic current to have a programmable magnitude in response to the respective control signal.

A switch 106 may comprise any electrical component that may complete or break an electrical circuit based on a control signal (e.g., an output signal vₒᵤₜ communicated from output stage 108) provided to such switch 106. For example, when output signal vₒᵤₜ is I, switch 106b may be activated (e.g., enabled, closed, turned on) such that hysteretic current i_{hyst}⁻ combines at a combining node 110 with intermediate current Δi to form combined current i_{comb} which may be input to input stage 108. As another example, when output signal vₒᵤₜ is 0, switch 106a may be activated (e.g., enabled, closed, turned on) such that hysteretic current i_{hyst}⁺ combines with intermediate current signal Δi at combining node 110 to form combined current i_{comb}. In some embodiments, hysteretic current i_{hyst}⁺ may have an approximately identical magnitude to hysteretic current i_{hyst}⁻. In other embodiments, such magnitudes may be significantly different.

In some embodiments, combining node 110 may have a lower impedance as compared with other electrical nodes of comparator 100.

In these and other embodiments, comparator 100 may be configured such that a magnitude of a hysteretic current signal (e.g., i_{hyst}⁺, i_{hyst}⁻) is no more than approximately ten percent of a magnitude of a current drawn by transconductance stage 102 from transconductance stage power supply voltage V_{gm} for powering transconductance stage 102. In these and other embodiments, comparator 100 may be configured such that a magnitude of a voltage swing on combining node 110 during operation of comparator 100 is no more than one half of a magnitude of a voltage swing of input voltage vₘ.

Output stage 108 may comprise any system, device, or apparatus configured to receive a current signal (e.g., combined current i_{comb}) and generate output signal V_{OUT} which is a function of such current signal. As shown in FIG. 1, output stage 108 may include an output stage power supply input for receiving an output stage power supply voltage V_{SUPPLY} for powering output stage 108 and its various components. In some embodiments, output stage power supply voltage V_{SUPPLY} may be different than transconductance stage power supply voltage V_{gm}. For example, in some embodiments, output stage power supply voltage V_{SUPPLY} may be less than transconductance stage power supply voltage V_{gm}.

Although FIG. 1 depicts comparator 100 having two hysteretic current sources 104 and two switches 106, in some embodiments, comparator 100 may have a single hysteretic current source 104 and a single switch 106. For example, in some embodiments, comparator 100 may include hysteretic current source 104a and switch 106a, but not hysteretic current source 104b and switch 106b. As another example, in other embodiments, comparator 100 may include hysteretic current source 104b and switch 106b, but not hysteretic current source 104a and switch 106a.

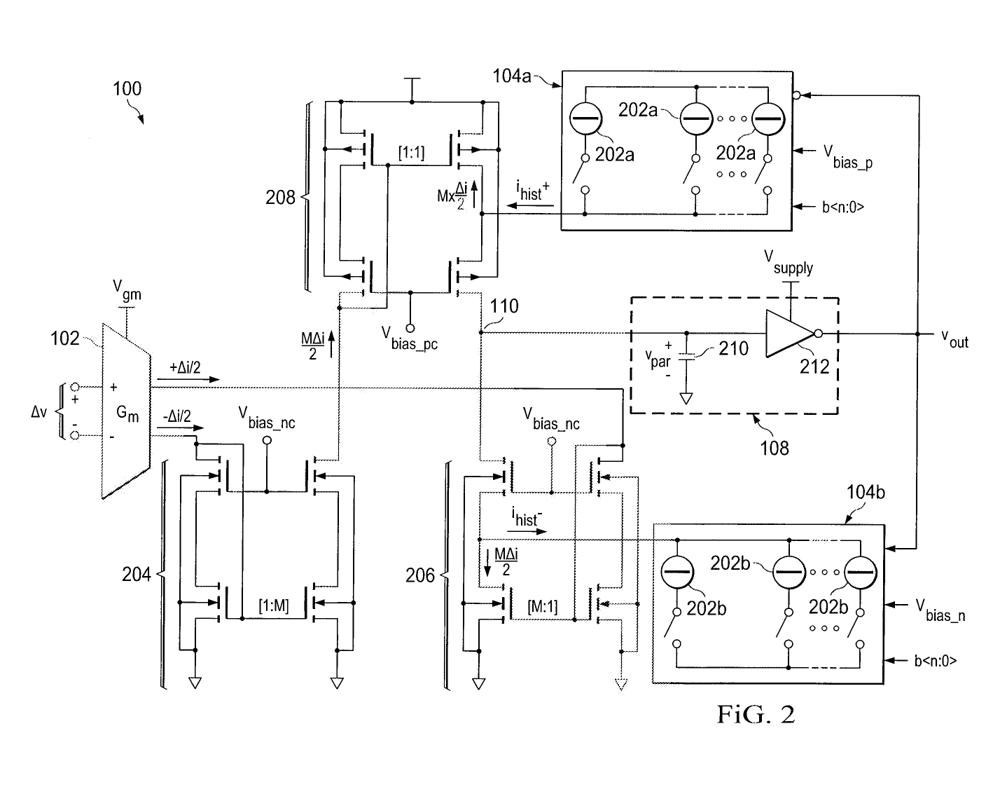

FIG. 2 illustrates detailed circuit diagram of components of example comparator 100 of FIG. 1, in accordance with embodiments of the present disclosure. As shown in FIG. 2, transconductance stage 102 may receive input voltage Δv and based thereon generate a differential current signal comprising a first output terminal current signal of Δi/2 and a second output terminal current signal of −Δi/2, for a net differential current signal of Δi. Comparator 100 may also include a plurality of current mirrors 204, 206, and 208 shown as cascaded current mirrors in FIG. 2, such that, in the absence of hysteretic current sources 104a and 104b. comparator 100 would generate an output current of i_{comb} of −MΔi, where M may represent a transistor size ratio of transistors present in cascoded current mirrors 204 and 206, as is known in the art. Such current −MΔi may be equivalent to the intermediate current Δi discussed above with reference to FIG. 1.

As shown in FIG. 2, each of hysteretic current sources 104a and 104b may be implemented using a respective current digital-analog converter (DAC), wherein hysteretic current source 104a is coupled to current mirror 208 in order to add hysteretic current i_{hyst}⁺ to a current generated by current mirror 208, and hysteretic current source 104b is coupled to current mirror 206 in order to add hysteretic current iₕᵢₛₜ⁻ to a current generated by current mirror 206. Each current DAC may include a plurality of switched current sources 202 (e.g., 202a and 202b) which are selectively enabled by a corresponding bit of a digital control signal b<n:0> shown in FIG. 2. Accordingly, a hysteretic current (e.g., iₕᵢₛₜ⁺ or iₕᵢₛₜ⁻) generated by such a current DAC may be a function of which switched current sources 202 are enabled, and thus may be a function of digital control signal b<n:0>.

Also as shown in FIG. 2, each of hysteretic current sources 104a and 104b may be enabled or disabled based on the value of output signal vₒᵤₜ. For example, if output signal vₒᵤₜ is digital value 1, hysteretic current source 104b may be enabled and hysteretic current source 104a may be disabled, while if output signal vₒᵤₜ is digital value 0, hysteretic current source 104a may be enabled and hysteretic current source 104b may be disabled. Such selective enabling and disabling of hysteretic current sources 104a and 104b may be performed by switches (not explicitly shown in FIG. 2) which may be equivalent in function to switches 106 of FIG. 1. Accordingly, when hysteretic current source 104a is enabled, combined current i_{comb} may be equal to MΔi+iₕᵢₛₜ⁺ and when hysteretic current source 104b is enabled, combined current i_{comb} may be equal to MΔi−iₕᵢₛₜ⁻.

In the embodiments represented by FIG. 2, output stage 108 may be implemented with a parasitic capacitance 210 of node 110 and a logic inverter 212. Accordingly, when the net combined current i_{comb} is positive, the charge and thus the voltage vₚₐᵣ on parasitic capacitance 210 may increase, and when the net current i_{comb} is negative, the charge and thus the voltage vₚₐᵣ on parasitic capacitance 210 may decrease. If such voltage vₚₐᵣ is above a threshold voltage V_{IH}, logic inverter 212 may output vₒᵤₜ=0, and if voltage vₚₐᵣ is below a threshold voltage V_{IL}, logic inverter 212 may output vₒᵤₜ=1. Thus, because switching of output stage 108 may be triggered by combined current i_{comb} charging and discharging parasitic capacitance 210, the programmable hysteretic current components iₕᵢₛₜ⁺ and iₕᵢₛₜ⁻ present in combined current i_{comb} may add programmable hysteresis to comparator 100.

To further illustrate functionality of comparator 100 of FIG. 2, assume comparator 100 of FIG. 2 is in a state in which output voltage vₒᵤₜ=1, parasitic voltage vₚₐᵣ is less than threshold voltage V_{IL}, and input voltage signal Δv is greater than zero. In such a scenario, current DAC 104b may be enabled, which sinks hysteretic current iₕᵢₛₜ₋. A subsequent input transition such that input voltage signal Δv falls below zero may then cause parasitic voltage vₚₐᵣ to charge towards threshold voltage V_{IH} such that when parasitic voltage vₚₐᵣ charges above threshold voltage V_{IH}, output voltage vₒᵤₜ may transition to 0, provided that i_{comb}, which equals MΔi−iₕᵢₛₜ⁻ is greater than zero, which may occur when current Δi is greater than iₕᵢₛₜ⁻/M.

Similarly, an output transition such that Δv>0 may cause parasitic voltage vₚₐᵣ to discharge towards threshold voltage V_{IL} such that when parasitic voltage vₚₐᵣ discharges below threshold voltage V_{IL}, output voltage vₒᵤₜ may transition to 1, provided that i_{comb}, which equals −MΔi+iₕᵢₛₜ⁺ is less than zero, which may occur when current Δi is lesser than iₕᵢₛₜ⁺/M. Thus, a net input-referred hysteresis voltage v_{hyst} for input voltage signal Δv may be given by:

$$\vert {v}_{hyst} \vert = \frac{\vert {i}_{hyst +} \vert + \vert {i}_{hyst -} \vert}{{MG}_{m}}$$

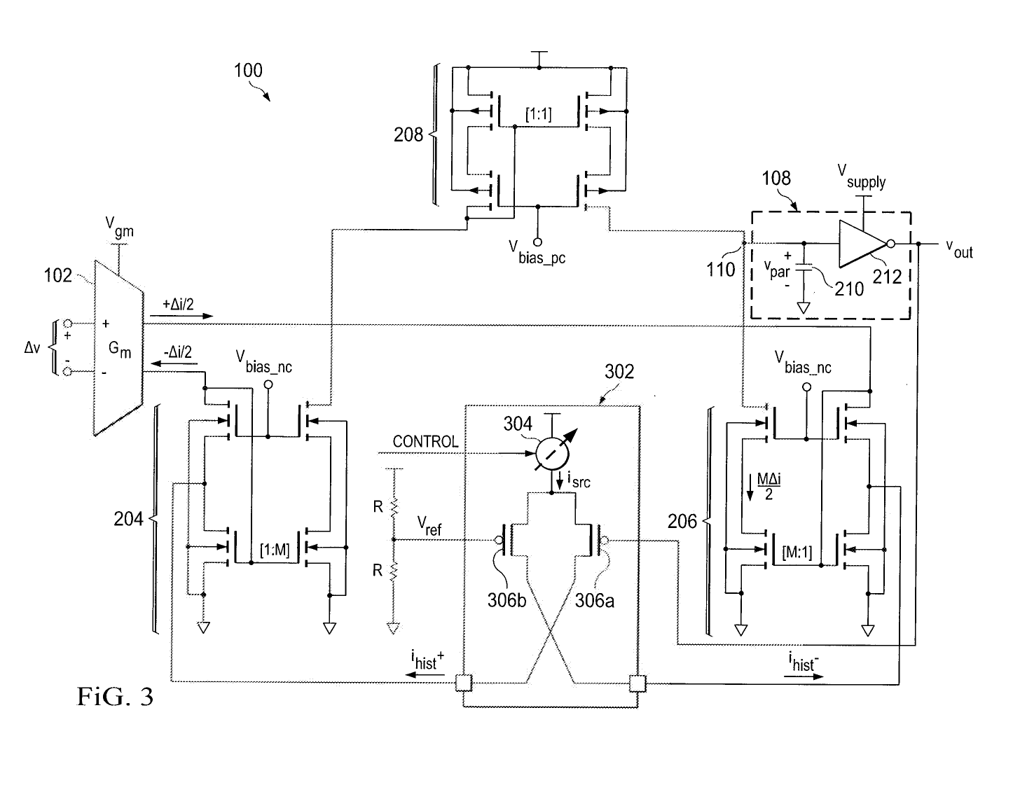

FIG. 3 illustrates an alternative detailed circuit diagram of components of example comparator 100 of FIG. 1, in accordance with embodiments the present disclosure. Comparator 100 shown in FIG. 3 may be similar in structure and functionality to that shown in FIG. 2, and thus only the differences between FIG. 2 and FIG. 3 will be discussed. In the embodiments represented by FIG. 3, hysteretic current sources are not implemented by current DACs as shown in FIG. 2, but may instead be implemented using current steering circuit 302 shown in FIG. 3. Current steering circuit 302 may comprise a programmable current source 304 with a programmable current controlled by a control signal CONTROL and two current steering transistors 306 (e.g., 306a and 306b). One such current steering transistor (e.g., current steering transistor 306b) may have its input (e.g., gate terminal) be biased at a reference voltage V_{ref} while the other (e.g., current steering transistor 306a) may have its input (e.g., gate terminal) coupled to output voltage vₒᵤₜ. Thus, in comparing the circuit of FIG. 3 to that of FIG. 1, current steering transistors 306a and 306b may be functionally equivalent to switches 106a and 106b, respectively, of FIG. 1, and programmable current source 304 may be equivalent to hysteretic current sources 104a and 104b, depending on which of current steering transistors 306 are enabled. In operation, when output signal vₒᵤₜ is logic 1, current steering transistor 306b may be enabled and current steering transistor 306a may be disabled, such that combined current i_{comb} equals M(ΔI−iₕᵢₛₜ⁻). Conversely, when output signal vₒᵤₜ is logic 0, current steering transistor 306a may be enabled and current steering transistor 306b may be disabled, such that combined current i_{comb} equals M(−ΔI+iₕᵢₛₜ⁺). Thus, because switching of output stage 108 may be triggered by combined current i_{comb} crossing zero, the programmable hysteretic current components Miₕᵢₛₜ⁺ and Miₕᵢₛₜ⁻ present in combined current i_{comb} may add programmable hysteresis to comparator 100.

To further illustrate functionality of comparator 100 of FIG. 3, assume comparator 100 of FIG. 3 is in a state in which output voltage vₒᵤₜ=1, parasitic voltage vₚₐᵣ is less than threshold voltage V_{IL}, and input voltage signal Δv is greater than zero. In such scenario, current steering transistor 306b may be enabled and current steering transistor 306a may be disabled, such that hysteretic current iₕᵢₛₜ, equals the current i_{src} output by programmable current source 304 and hysteretic current iₕᵢₛₜ₊ equals zero. A subsequent input transition such that input voltage signal Δv falls below zero may then cause parasitic voltage vₚₐᵣ to charge towards threshold voltage V_{IH} such that when parasitic voltage v_{out par} charges above threshold voltage V_{IH}, output voltage vₒᵤₜ may transition to 0, provided that i_{comb}, which equals M(Δi−iₕᵢₛₜ⁻) is greater than zero, which may occur when current Δi is greater than iₕᵢₛₜ⁻.

Similarly, an output transition such that Δv>0 may cause parasitic voltage vₚₐᵣ to discharge towards threshold voltage V_{IL} such that when parasitic voltage vₚₐᵣ discharges below threshold voltage V_{IL}, output voltage vₒᵤₜ may transition to 1, provided that i_{comb}, which equals M(−Δi+iₕᵢₛₜ⁺) is less than zero, which may occur when current Δi is lesser than iₕᵢₛₜ⁺. Thus, a net input-referred hysteresis voltage v_{hyst} for input voltage signal Δv may be given by:

$$\vert {v}_{hyst} \vert = \frac{\vert {i}_{hyst +} \vert + \vert {i}_{hyst -} \vert}{{G}_{m}}$$

The systems and methods described herein may provide one or more advantages over existing approaches for implementing hysteresis in a comparator. For example, level shifting is performed in the current domain by exploiting existing comparator architecture, and avoids the need for explicit level shifters. In addition, current mode hysteresis is enabled through use of a programmable current source and summation at a low impedance node which settles quickly, thus allowing for increased speed over existing approaches. In addition, hysteresis can be disabled without affecting normal operation of the comparator. Furthermore, in the current-DAC based implementation of FIG. 2, current DACs may be implemented as replicas of the main tail current source of the transconductance stage, thus minimizing mismatch variations, and current generated by current DACs may be digitally controlled to a fine precision.

As used herein, when two or more elements are referred to as “coupled” to one another, such term indicates that such two or more elements are in electronic communication whether connected indirectly or directly, with or without intervening elements.

This disclosure encompasses all changes substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to enabled to, operable to, or operative to perform a particular function encompasses that apparatus system, or component, whether or not it or that particular function is activated, turned on or unlocked, as long as that apparatus, system, or component is so adapted, arranged capable, configured, enabled, operable, or operative.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosures have been described in detail, it should be understood that various changes, substitutions, and alterations could be made hereto without departing from the spirit and scope of the disclosure.

What is claimed is:

1. A comparator comprising:
a transconductance stage having an input configured to receive an input voltage and generate an intermediate current responsive to the input voltage;
a hysteretic current source configured to generate a hysteretic current;
an output stage configured to generate an output signal based at least on the intermediate current; and
a switch responsive to the output stage and configured to combine the intermediate current and the hysteretic current to generate a combined current, such that the output stage generates the output signal based at least on the intermediate current and the hysteretic current when the output signal has a first value.

2. The comparator of claim 1, wherein the hysteretic current source comprises a control input configured to receive a control signal and a magnitude of the hysteretic current is programmable in response to the control signal.

3. The comparator of claim 1, wherein the hysteretic current source comprises a current digital to analog converter configured to generate the hysteretic current responsive to a digital control signal for programming the hysteretic current.

4. The comparator of claim 1, wherein the hysteretic current source comprises a current steering circuit configured to generate the hysteretic current responsive to a digital control signal for programming a programmable current source of the current steering circuit.

5. The comparator of claim 1, wherein:
the transconductance stage comprises a transconductance stage power supply input for receiving a transconductance stage power supply voltage for powering the transconductance stage; and
the output stage comprises an output stage power supply input for receiving an output stage power supply voltage for powering the output stage, wherein the output stage power supply voltage is different than the transconductance stage power supply voltage.

6. The comparator of claim 1, wherein:
the transconductance stage comprises a transconductance stage power supply input for receiving a transconductance stage power supply voltage for powering the transconductance stage; and
the output stage comprises an output stage power supply input for receiving an output stage power supply voltage for powering the output stage, wherein the output stage power supply voltage is less than the transconductance stage power supply voltage.

7. The comparator of claim 1, wherein a magnitude of the hysteretic current signal is no more than approximately ten percent of a magnitude of a current drawn by the transconductance stage from a transconductance stage power supply voltage for powering the transconductance stage.

8. The comparator of claim 1, further comprising a combining node at which the intermediate current is combined with hysteretic current to generate the combined current, wherein a magnitude of a voltage swing on the combining node during operation of the comparator is no more than one half of a magnitude of a voltage swing of the input voltage.

9. The comparator of claim 1, further comprising:
a second hysteretic current source configured to generate a second hysteretic current; and
one of the switch and a second switch configured to combine the intermediate current and the second hysteretic current to generate a second combined current, such that the output stage generates the output signal based at least on the intermediate current and the second hysteretic current when the output signal has a second value.

10. The comparator of claim 9, wherein the switch and the second switch are configured such that:
the output stage generates the output signal based on the combined current when the output signal has the first value; and
the output stage generates the output signal based on the second combined current when the output signal has the second value.

11. A method comprising:
receiving an input voltage;
generating an intermediate current responsive to the input voltage by a transconductance stage;
generating a hysteretic current with a hysteretic current source;
generating an output signal based at least on the intermediate current by an output stage; and
controlling a switch responsive to the output stage such that the intermediate current and the hysteretic current are combined to generate a combined current, such that the output signal is based at least on the intermediate current and the hysteretic current when the output signal has a first value.

12. The method of claim 11, wherein generating the hysteretic current comprises:
receiving a control signal for programming the hysteretic current; and
controlling a magnitude of the hysteretic current in response to the control signal.

13. The method of claim 11, wherein generating the hysteretic current comprises:
receiving a digital control signal for programming the hysteretic current; and
performing a digital to analog conversion of the digital control signal to generate the hysteretic current.

14. The method of claim 11, wherein the hysteretic current source comprises a current steering circuit and the method further comprises generating the hysteretic current responsive to a digital control signal for programming a programmable current source of the current steering circuit.

15. The method of claim 11, wherein:
the transconductance stage comprises a transconductance stage power supply input for receiving a transconductance stage power supply voltage for powering the transconductance stage; and
the output stage comprises an output stage power supply input for receiving an output stage power supply voltage for powering the output stage, wherein the output stage power supply voltage is different than the transconductance stage power supply voltage.

16. The method of claim 11, wherein:
the transconductance stage comprises a transconductance stage power supply input for receiving a transconductance stage power supply voltage for powering the transconductance stage; and
the output stage comprises an output stage power supply input for receiving an output stage power supply voltage for powering the output stage, wherein the output stage power supply voltage is less than the transconductance stage power supply voltage.

17. The method of claim 11, wherein a magnitude of the hysteretic current signal is no more than approximately ten percent of a magnitude of a current drawn by the transconductance stage from a transconductance stage power supply voltage for powering the transconductance stage.

18. The method of claim 11, wherein:
the intermediate current and the hysteretic current are combined at a combining node to generate the combined current; and
a magnitude of a voltage swing on the combining node during operation is no more than one half of a magnitude of a voltage swing of the input voltage.

19. The method of claim 11, further comprising:
generating a second hysteretic current with a second hysteretic current source; and
controlling a second switch responsive to the output stage such that the intermediate current and the second hysteretic current are combined to generate a second combined current, such that the output signal is based at least on the intermediate current and the second hysteretic current when the output signal has a second value.

20. The method of claim 19, further comprising:
generating the output signal based on the combined current when the output signal has the first value; and
generating the output signal based on the second combined current when the output signal has the second value.
